(19) United States
(12) Patent Application Publication
(10) Pub. No.: US 2017/0052218 A1
(43) Pub. Date: Feb. 23, 2017

(54) TESTING UNIT AND TESTING APPARATUS USING THE SAME

(71) Applicants: GLOBAL UNICHIP CORPORATION, HSINCHU CITY (TW); TAIWAN SEMICONDUCTOR MANUFACTURING CO., LTD., HSINCHU (TW)

(72) Inventors: Chih-Chieh LIAO, Taipei City (TW); Yu-Min SUN, New Taipei City (TW); Chih-Feng CHENG, Taoyuan City (TW)

(21) Appl. No.: 14/990,773

(22) Filed: Jan. 7, 2016

(30) Foreign Application Priority Data
Aug. 19, 2015 (TW) 104127029

(51) Int. Cl. G01R 1/067; G01R 31/28

(52) U.S. Cl. CPC G01R 1/06755; G01R 1/06716; G01R 31/2886

(57) ABSTRACT

A testing apparatus includes a substrate and a testing unit. The testing unit includes a testing pin, in which the testing pin is strip-shaped and has a connecting portion, a first end, and a second end. The first end and the second end of the testing pin are opposite to each other. The first end and the second end are connected to the substrate. The connecting portion is located between the first end and the second end, and the connecting portion protrudes from the substrate to become arc-shaped.

### RELATED APPLICATIONS

This application claims priority to Taiwanese Application Serial Number 104127029, filed Aug. 19, 2015, which is herein incorporated by reference.

### BACKGROUND

Technical Field

The present disclosure relates to a testing unit and a testing apparatus using the same.

Description of Related Art

With the development of technology, electronic devices using integrated circuit (IC) devices are increasing. In this regard, in a fabrication process of an IC device or other electronic devices, a testing apparatus is used to test the performance and functions of the IC device in a packaged state, such as in a quad flat package (QFP). During the testing process, the QFP contacts the testing apparatus to establish an electrical communication path. Thus, in the testing process, the QFP is fixed at a proper position in the testing apparatus. After the testing process is completed, the QFP is move out of the testing apparatus.

However, after the testing apparatus has performed several times of test, testing pins of the testing apparatus may be worn out. Once the worn-out occurs, the testing result with respect to the QFP may become abnormal, such that the testing result is affected.

### SUMMARY

An aspect of the present disclosure provides a testing apparatus including a substrate and testing units, in which each of the testing units includes a testing pin. A connecting portion of the testing pin protrudes from the substrate to become arc-shaped. Through the arc-shaped connecting portion, the force from a chip to be tested can be distributed by the testing pin, such that the stress on the testing pin may not be concentrated and accumulated at a specific position, thereby preventing the testing pin from breaking due to material fatigue. In addition, during a testing operation, since no relative slide between a pin of the chip to be tested and the connecting portion of the testing pin occurs, a situation that the material forming the pin of the chip to be tested remains on a surface of the testing pin is improved.

An aspect of the present disclosure is to provide a testing apparatus including a substrate and a testing unit. The testing unit includes a testing pin, in which the testing pin is strip-shaped and has a connecting portion, a first end, and a second end. The first end and the second end of the testing pin are opposite to each other. The first end and the second end are connected to the substrate. The connecting portion is located between the first end and the second end, and the connecting portion protrudes from the substrate to become arc-shaped.

In some embodiments, each point at a boundary of the arc-shaped connecting portion facing away from the substrate has a tangent.

In some embodiments, the arc-shaped connecting portion has a first concave surface facing the substrate.

In some embodiments, the arc-shaped connecting portion has a first concave surface and a second concave surface. The first concave surface faces the substrate, and the second concave surface faces away from the substrate.

In some embodiments, at least one inflection point is present at a boundary of the arc-shaped connecting portion facing away from the substrate.

In some embodiments, at least one turning point is present at a boundary of the arc-shaped connecting portion facing away from the substrate.

In some embodiments, the testing unit further includes a pair of connecting pates. The connecting plates are respectively disposed at the first end and the second end of the testing pin, and the pair of the connecting plates and the testing pin are monolithically formed.

In some embodiments, the pair of the connecting plates is located within a vertical projection of the connecting portion on the substrate.

In some embodiments, the pair of the connecting plates is located outside a vertical projection of the connecting portion on the substrate.

In some embodiments, the testing pin is made of a memory alloy.

### BRIEF DESCRIPTION OF THE DRAWINGS

FIG. 1A is a schematic top view of a testing apparatus according to a first embodiment of the present disclosure;

FIG. 1B is a schematic cross-sectional diagram of the testing apparatus taken along a line B-B of FIG. 1A;

FIG. 1C is a schematic diagram showing a testing pin of FIG. 1B contacting a chip to be tested;

FIG. 2A is a schematic cross-sectional diagram of a testing apparatus taken along the same cut line position used in FIG. 1B according to a second embodiment of the present disclosure;

FIG. 2B is a schematic diagram showing a testing pin of FIG. 2A contacting a chip to be tested;

FIG. 3A is a schematic cross-sectional diagram of a testing apparatus taken along the same cut line position used in FIG. 1B according to a third embodiment of the present disclosure;

FIG. 3B is a schematic diagram showing a testing pin of FIG. 3A contacting a chip to be tested; and

FIGS. 4A-4D are schematic cross-sectional diagrams of testing units of testing apparatuses taken along the same cut line position used in FIG. 1B according to various embodiments of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

It will be understood that, although the terms first, second, third etc. may be used herein to describe various elements, components, regions, layers and/or sections, these elements, components, regions, layers and/or sections should not be limited by these terms.

In view of a problem that testing pins of an testing apparatus may be worn out due to several times of usage, embodiments of the present disclosure provide a testing apparatus including a substrate and testing units, in which each of the testing units includes a testing pin. A connecting portion of the testing pin protrudes from the substrate to become arc-shaped. Through the arc-shaped connecting portion, the force from a chip to be tested can be distributed by the testing pin, such that the stress on the testing pin may not be concentrated and accumulated on a specific position. Therefore, since the stress on the testing pin is not concentrated and accumulated on a specific position, a situation that the testing pin may tend to be broken due to material fatigue can be prevented, thereby reducing the worn-out of the testing pin of the testing apparatus.

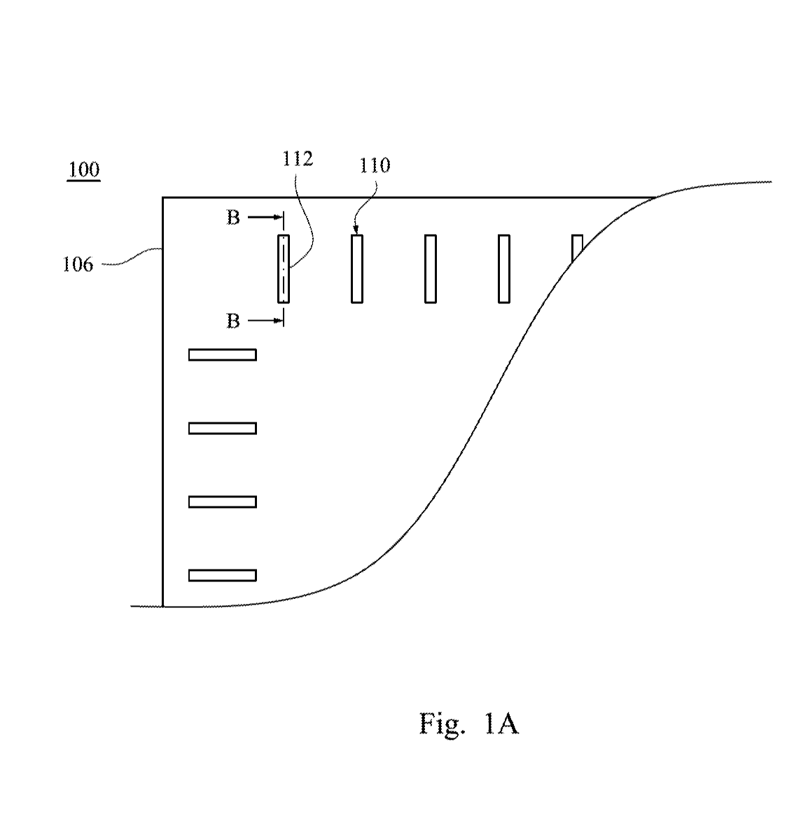

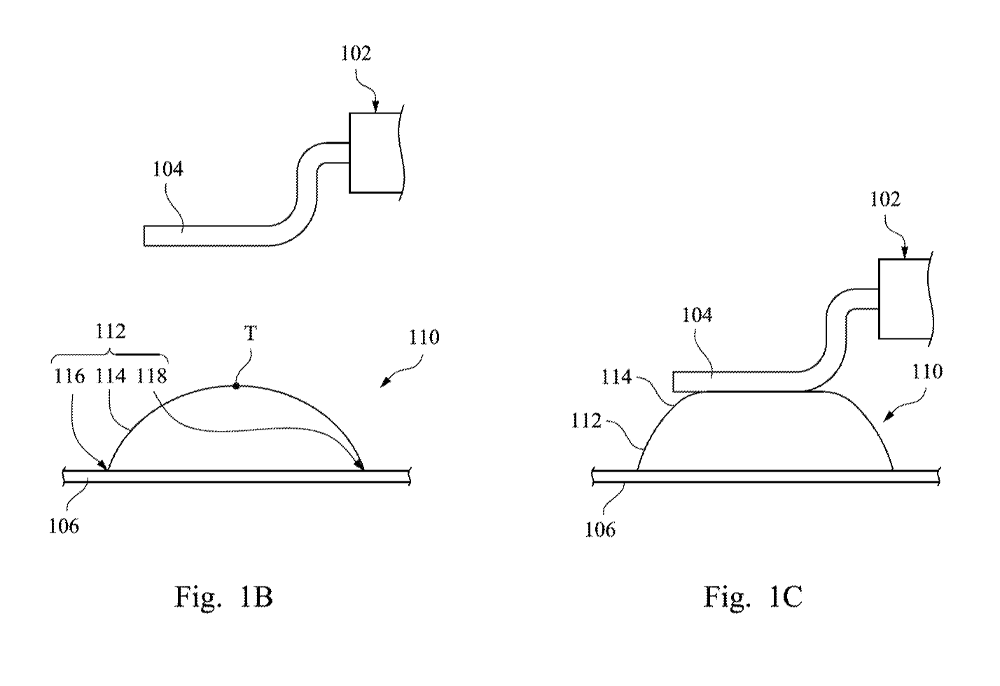

FIG. 1A is a schematic top view of a testing apparatus 100 according to a first embodiment of the present disclosure. FIG. 1B is schematic a cross-sectional diagram of the testing apparatus 100 taken along the line B-B of FIG. 1A. The testing apparatus 100 includes a substrate 106 and testing units 110. In addition, the structure illustrated in FIG. 1A is one part of the testing apparatus 100. In other words, although the testing units 110 illustrated in FIG. 1A on the substrate 106 are arranged in a L-shape, the arrangement of the testing units 110 is not limited thereto. However, a person having ordinary skill in the art may choose a proper arrangement of the testing units 110. For example, the testing units 110 disposed on the substrate 106 may be arranged in a L-shape, a rectangle or another arrangement that can match elements to be tested.

The substrate 106 may be a circuit board including a plurality of leads. Each of the testing units 110 includes a testing pin 112, in which the testing pin 112 is strip-shaped and has a connecting portion 114, a first end 116, and a second end 118. The first end 116 and the second end 118 of the testing pin 112 are opposite to each other. The first end 116 and the second end 118 are connected to the substrate 106. For example, the first end 116 and the second end 118 of the testing pin 112 can be respectively connected to the corresponding leads of the substrate 106. Thus, the substrate 106 can provide the first end 116 and the second end 118 with a horizontal level, such that the first end 116 and the second end 118 are located at the same horizontal level. The connecting portion 114 is located between the first end 116 and the second end 118, and the connecting portion 114 protrudes from the substrate 106 to become arc-shaped. Furthermore, the testing pin 112 can be made of a metal material. In addition, in some embodiments, the testing apparatus 100 can further include a colloid structure (not illustrated). For example, the colloid structure may be a silica gel structure or a rubber structure. The colloid structure can be disposed at the first end 116 and the second end 118 of the testing pin 112, so as to prevent the testing pin 112 from moving or vibrating during a testing operation.

As shown in FIG. 1B, the testing pin 112 of the testing unit 110 is configured to contact a pin 104 of a chip 102 to be tested, so as to build an electrical connection therebetween. When the chip 102 to be tested contacts the testing pin 112, the pin 104 of the chip 102 can contact the connecting portion 114 of the testing pin 112. Furthermore, when the chip 102 to be tested contacts the testing pin 112, the pin 104 of the chip 102 may apply a force to the testing pin 112 along a direction toward the substrate 106. In this regard, since the connecting portion 114 is arc-shaped, the force applied to the connecting portion 114 along the direction toward the substrate 106 can be distributed by the arc shape. In other words, since the testing pin 112 can distribute the force provided by the chip 102, the stress generated by the chip 102 at the testing pin 112 may not be concentrated and accumulated on a specific position. Therefore, through the arc-shaped connecting portion 114, since the stress at the testing pin 112 may not be concentrated and accumulated on the specific position, a situation that the testing pin 112 may tend to be broken due to the material fatigue is prevented, thereby increasing the usage times of the testing pin 112.

In the present embodiment, each of all points at a boundary of the arc-shaped connecting portion 114 facing away from the substrate 106 has a tangent, in which the boundary of the arc-shaped connecting portion 114 facing away from the substrate 106 can be considered as an arc surface. Thus, the arc-shaped connecting portion 114 has a first concave surface facing the substrate 106. Therefore, the connecting portion 114 may not have a sharp point at which stress concentration may occur (i.e., the sharp point may be an apex or a corner formed when the connecting portion 114 is folded). Therefore, since the testing pin 112 does not have the sharp point at which stress concentration is likely to occur, the usage times of the testing pin 112 is increased.

Furthermore, at least one turning point T is present at the boundary of the arc-shaped connecting portion 114 facing away from the substrate 106. A vertical distance between the turning point T and the substrate 106 is the maximum one of distances between the connecting portion 114 and the substrate 106. At least one tangent is present at the turning point T of the connecting portion 114, in which a slope of the tangent relative to the substrate 106 can be considered as zero (i.e., the turning point T has at least one tangent extending along a direction which is parallel to the substrate 106). Therefore, when the pin 104 of the chip 102 to be tested contacts the connecting portion 114, the pin 104 of the chip 102 may reach the turning point T first, as shown in FIG. 1C, in which FIG. 1C is a schematic diagram showing the testing pin 112 of FIG. 1B contacting the chip 102 to be tested.

In FIG. 1C, during the testing operation, the shape of the testing pin 112 may be deformed by the force from the pin 104 of the chip 102 to be tested. After the testing operation, the pin 104 of the chip 102 moves from the testing pin 112 toward a direction facing away from the substrate 106. After the pin 104 of the chip 102 moves away from the testing pin 112, since the testing pin 112 made of the metal material is elastic, the testing pin 112 can return to its original shape, so as to perform a next testing operation. In order to enable the testing unit 110 or the testing pin 112 thereof to return to its original shape after every testing operation, the testing unit 110 or the testing pin 112 thereof can be made of a memory alloy. The memory alloy includes Au—Cd, Ag—Cd, Cu—Zn, Cu—Zn—Al, Cu—Zn—Sn, Cu—Zn—Si, Cu—Sn, Cu—Zn—Ga, In—Ti, Au—Cu—Zn, NiAl, Fe—Pt, Ti—Ni, Ti—Ni—Pd, Ti—Nb, Fe—Mn—Si or a combination thereof.

In addition, under this configuration, a relative slide between the pin 104 of the chip 102 to be tested and the connecting portion 114 of the testing pin 112 does not occur during the testing operation, and thus the pin 104 of the chip 102 to be tested does not slide at the connecting portion 114 of the testing pin 112 or on a surface thereof. Therefore, a situation that the surface of the testing pin 112 is damaged due to scrape by the pin 104 of the chip 102 can be improved. On the other hand, the substance composing the pin 104 of the chip 102 to be tested (e.g. metal) may not be transferred to the surface of the testing pin 112 with the relative slide, such that a situation that the substance composing the pin 104 of the chip 102 to be tested (e.g. metal) is remained on the surface of the testing pin 112 is improved, thereby reducing the affection with respect to the testing result.

As described above, the testing apparatus of the present disclosure includes the substrate and the testing units, in which each of the testing units includes the testing pin. By the arc-shaped connecting portion, the stress on the testing pin may not be focused and concentrated on the specific position, such that the situation that the testing pin may tend to be broken due to the material fatigue is prevented, thereby increasing the usage times of the testing pin. In addition, during the test operation, since the relative slide between the pin of the chip to be tested and the connecting portion of the testing pin is not generated, the situation that the substance composing the pin of the chip to be tested (e.g. metal) is remained on the surface of the testing pin is improved, thereby preventing the testing result from being affected.

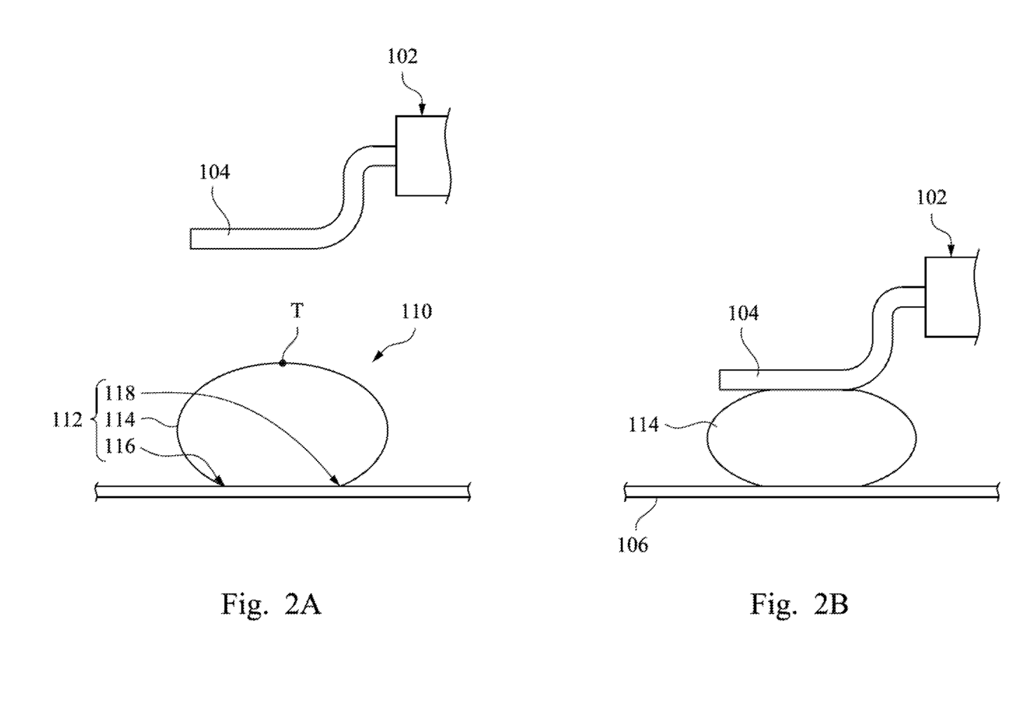

FIG. 2A is a cross-section diagram of a testing apparatus 110 with the same cross-section as FIG. 1B according to a second embodiment of the present disclosure. FIG. 2B is a schematic diagram that a testing pin 112 illustrated in FIG. 2A contacts a chip 102 to be tested. The difference between the present embodiment and the first embodiment is that the shape of the connecting portion 114 of the present embodiment is similar to a whole circle relatively to the connecting portion 114 of the first embodiment.

In the present embodiment, since the shape of the connecting portion 114 of the present embodiment is similar to a whole circle relatively to the connecting portion 114 of the first embodiment, the horizontal distance between the first end 116 and the second end 118 is smaller than the maximum one of the horizontal widths of the connecting portion 114. Similarly, by the shape of the connecting portion 114 of the present embodiment, the force provided by the ping 104 of the chip 102 to be tested on the testing pin 112 can be scattered, such that the situation that the testing pin 112 may tend to be broken due to the material fatigue is prevented, thereby increasing the usage times of the testing pin 112.

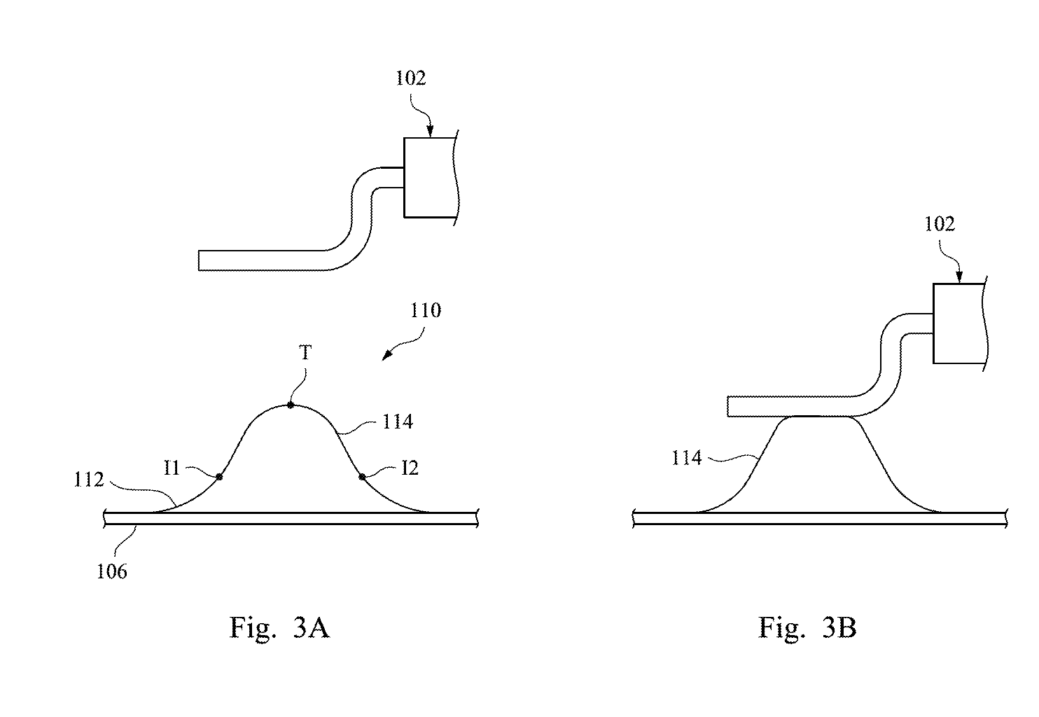

FIG. 3A is a cross-section diagram of a testing apparatus 110 with the same cross-section as FIG. 1B according to a third embodiment of the present disclosure. FIG. 3B is a schematic diagram that a testing pin 112 illustrated in FIG. 3A contacts a chip 102 to be tested. The difference between the present embodiments and the first embodiment is that the arc-shaped connecting portion 114 has at least two concave surfaces.

The arc-shaped connecting portion 114 has a first concave surface and a second concave surfaces. The first concave surface faces the substrate 106, and the arc-shaped connecting portion 114 has at least one turning point T at a boundary of the first concave surface. The second concave surfaces face away the substrate 106. Furthermore, inflection points I1 and I2 are present at a boundary of the arc-shaped connecting portion 114 facing away the substrate 106. In the present embodiment, the number of the first concave surface is one, and the number of the second concave surfaces is two. The second concave surfaces are respectively present at two opposite sides of the first concave surface, and one of the inflection points I1 and I2 is respectively present between the first concave surface and corresponding one of the second concave surfaces. By the shape of the connecting portion 114, during the testing operation, the second concave surface can provide the connecting portion 114 with a buffer effect when the shape of the connecting portion 114 is changed, such that the changed shape of the connecting portion 114 may be predictably controlled, thereby preventing the testing result from being inaccurate.

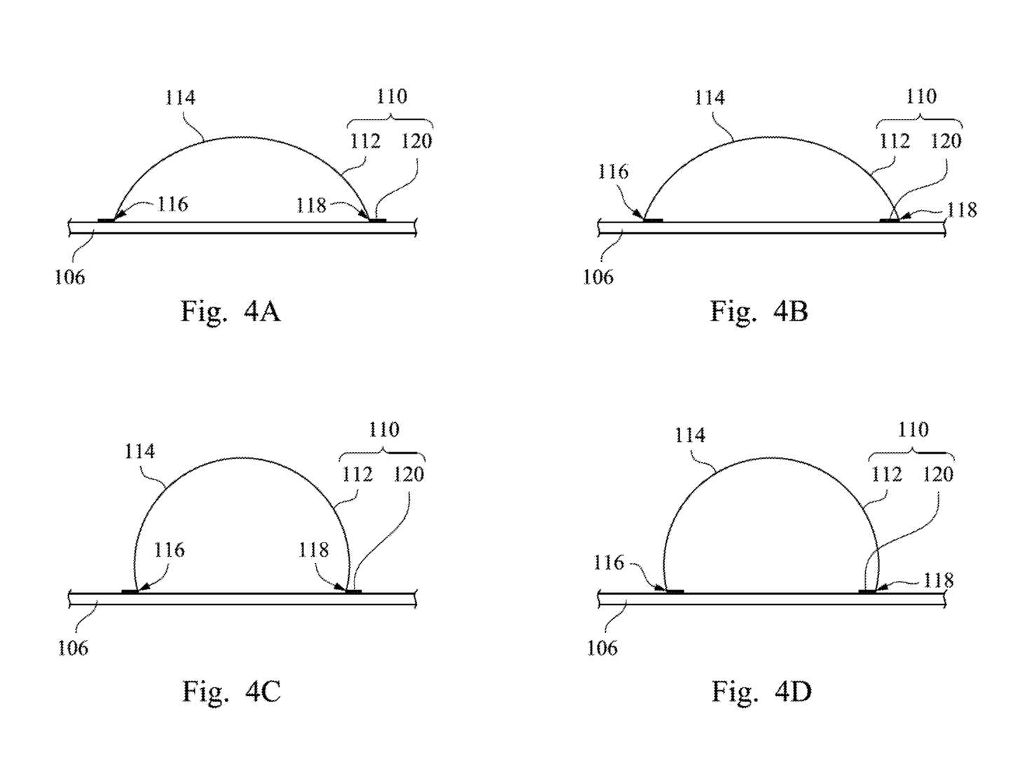

FIGS. 4A-4D are cross-section diagrams of testing units 110 of testing apparatuses with the same cross-section as FIG. 1B according to various embodiments of the present disclosure. The shape of each of the connecting portions 114 illustrated in FIGS. 4A and 4B are the same as the first embodiment, and the shape of each of the connecting portions 114 illustrated in FIGS. 4C and 4D are the same as the second embodiment. The difference between the present embodiment and one of the first and second embodiments is that the testing unit 110 of the present embodiment further includes a pair of connecting plates 120. The connecting plates 120 are respectively disposed at the first end 116 and the second end 118 of the testing pin 112, and the pair of the connecting plates 120 and the testing pin 112 are monolithically formed.

By using the connecting plates 120, the fixing strength between the testing unit 110 and the substrate 106 can be enhanced, thereby preventing the testing unit 110 from separating from the substrate 106. Furthermore, in the present embodiment, the pair of the connecting plates 120 can be disposed within or outside a vertical projection of the connecting portion 114 on the substrate 106.

For example, as shown in FIGS. 4A and 4C, the connecting plates 120 are located outside the vertical projection of the connecting portion 114 on the substrate 106. On the other hand, as shown in FIGS. 4B and 4D, the connecting plates 120 are located within the vertical projection of the connecting portion 114 on the substrate 106. Moreover, the overall shape of the testing unit 110 illustrated in FIG. 4D can be considered as a Ω shape. However, a person having ordinary skill in the art may place the connecting plates 120 at proper positions, so as to align the testing unit 110 to the substrate 106.

As described above, the testing apparatus of the present disclosure includes the substrate and the testing units, in which each of the testing units includes the testing pin. The connecting portion of the testing pin protrudes from the substrate to become arc-shaped. By using the arc-shaped connecting portion, the force from the chip to be tested can be distributed by the testing pin, such that the stress on the testing pin may not be concentrated and accumulation on a specific position, thereby preventing the testing pin from breaking due to material fatigue. In addition, during the testing operation, since the relative slide between the pin of the chip to be tested and the connecting portion of the testing pin does not occur, the situation that the material forming the pin of the chip to be tested remains on the surface of the testing pin can be improved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the invention. In view of the foregoing, it is intended that the present disclosure cover modifications and variations of the present disclosure provided they fall within the scope of the following claims.

What is claimed is:

1. A testing unit, comprising:
a testing pin which is strip-shaped and has a connecting portion, a first end, and a second end, wherein the first end and the second end of the testing pin are opposite to each other, the first end and the second end are located at the same horizontal level and are connected with each other by the connecting portion, and the connecting portion protrudes from the horizontal level to become arc-shaped.

2. The testing unit of claim 1, wherein each point at a boundary of the arc-shaped connecting portion facing away from the horizontal level has a tangent.

3. The testing unit of claim 1, wherein the arc-shaped connecting portion has a first concave surface facing the horizontal level.

4. The testing unit of claim 1, wherein the arc-shaped connecting portion has a first concave surface and a second concave surface, the first concave surface faces the horizontal level, and the second concave surface faces away from the horizontal level.

5. The testing unit of claim 4, wherein at least one inflection point is present at a boundary of the curve-shaped connecting portion.

6. The testing unit of claim 1, wherein at least one turning point is present at a boundary of the arc-shaped connecting portion.

7. The testing unit of claim 1, further comprising a pair of connecting plates, wherein the connecting plates are respectively disposed at the first end and the second end of the testing pin, and the pair of the connecting plates and the testing pin are one-piece integrated.

8. The testing unit of claim 7, wherein the pair of the connecting plates is located within a vertical projection of the connecting portion on the horizontal level.

9. The testing unit of claim 7, wherein the pair of the connecting plates is located outside a vertical projection of the connecting portion on the horizontal level.

10. The testing unit of claim 1, wherein the testing pin is made of a memory alloy.

11. A testing apparatus, comprising:
a substrate; and
a testing unit comprising a testing pin which is strip-shaped and has a connecting portion, a first end, and a second end, wherein the first end and the second end of the testing pin are opposite to each other and are connected to the substrate, and the connecting portion is located between the first end and the second end, and the connecting portion protrudes from the substrate to become arc-shaped.

12. The testing apparatus of claim 11, wherein each point at a boundary of the arc-shaped connecting portion facing away from the substrate has a tangent.

13. The testing apparatus of claim 11, wherein the arc-shaped connecting portion has a first concave surface facing the substrate.

14. The testing apparatus of claim 11, wherein the arc-shaped connecting portion has a first concave surface and a second concave surface, wherein the first concave surface faces the substrate, and the second concave surface faces away from the substrate.

15. The testing apparatus of claim 14, wherein at least one inflection point is present at a boundary of the arc-shaped connecting portion facing away from the substrate.

16. The testing apparatus of claim 11, wherein at least one turning point is present at a boundary of the arc-shaped connecting portion facing away from the substrate.

17. The testing apparatus of claim 11, wherein the testing unit further comprises a pair of connecting plates, wherein the connecting plates are respectively disposed at the first end and the second end of the testing pin, and the pair of the connecting plates and the testing pin are one-piece integrated.

18. The testing apparatus of claim 17, wherein the pair of the connecting plates is located within a vertical projection of the connecting portion on the substrate.

19. The testing apparatus of claim 17, wherein the pair of the connecting plates is located outside a vertical projection of the connecting portion on the substrate.

20. The testing apparatus of claim 1, wherein the testing pin is made of a memory alloy.
